(19) United States
(12) Patent Application Publication
(10) Pub. No.: US 2011/0248145 A1
(43) Pub. Date: Oct. 13, 2011

(54) SOLID-STATE IMAGING DEVICE, DIGITAL CAMERA, AND ANALOG-TO-DIGITAL CONVERSION METHOD

(75) Inventor: Nozomi TANAKA, Kyoto (JP)

(73) Assignee: PANASONIC CORPORATION, Osaka (JP)

(21) Appl. No.: 13/161,768

(22) Filed: Jun. 16, 2011

Related U.S. Application Data
(63) Continuation of application No. PCT/JP2009/007058, filed on Dec. 21, 2009.

(30) Foreign Application Priority Data
Dec. 25, 2008 (JP) 2008-331626

(51) Int. Cl. H01L 27/146

(52) U.S. Cl. 250/208.1

(57) ABSTRACT

A solid-state imaging device according to the present invention includes: a pixel portion including a plurality of unit pixels arranged in a matrix; a column signal line provided per column in the pixel portion; an AD conversion unit which converts a voltage of a pixel signal into a digital value by performing counting until a reference signal reaches the voltage of the pixel signal from the column signal line; and a clock signal generating unit which generates, to the AD conversion unit, a counter clock for the counting, and the clock signal generating unit switches, during a period of the AD conversion, a frequency of the counter clock from a first frequency to a second frequency that is different from the first frequency.

### CROSS REFERENCE TO RELATED APPLICATION

This is a continuation application of PCT application No. PCT/JP2009/007058 filed on Dec. 21, 2009, designating the United States of America.

### BACKGROUND OF THE INVENTION

(1) Field of the Invention

The present invention relates to solid-state imaging devices such as a MOS image sensor, and particularly relates to a solid-state imaging device, a digital camera, and an analog-to-digital (AD) conversion method for what is called a column solid-state imaging device which sequentially outputs each pixel signal by accumulating, in a column region provided for each pixel, pixel signals obtained through a photoelectric conversion region and sequentially selecting the column region.

(2) Description of the Related Art

Conventionally, an imaging device which is suggested for the method of expanding dynamic range of the MOS image sensor accumulates, in a detection node, charges obtained by photoelectric conversion by a photodiode during a first exposure period, and further accumulates, in the detection node, after discharging part of the charges accumulated in the detection node, charges obtained by the photodiode during a second exposure period that is shorter than the first exposure period (for example, Patent Reference 1: Japanese Unexamined Patent Application Publication No. 2000-23044)

In addition, another suggested method is a method of expanding the dynamic range by performing analog-to-digital (AD) conversion on image pixels a plurality of times with different resolutions, and synthesizing the signals after the AD conversion (for example, Patent Reference 2: Japanese Unexamined Patent Application Publication No. 2008-124842).

### SUMMARY OF THE INVENTION

However, since the imaging device in Patent Reference 1 uses the detection unit for expanding the dynamic range, there is a possibility of generating unevenness in dark colors or KTC noise (reset noise) due to detection leakage, thus causing deterioration in image quality. In addition, the solid-state imaging device in Patent Reference 2 requires a line memory for storing signals to be synthesized or a circuit for performing synthesis processing, thus increasing circuit size.

Thus, an object of the present invention is to provide a solid-state imaging device whose dynamic range is expanded using a simple configuration.

To achieve the above object, a solid-state imaging device according to an aspect of the present invention includes: an imaging unit having a plurality of pixels arranged in a matrix; a column signal line provided per column in the imaging unit; an analog-to-digital (AD) conversion unit which converts, into a digital value, a voltage of a pixel signal from the column signal line by performing counting for a period of time until a ramp waveform signal reaches the voltage of the pixel signal; and a clock signal generating unit which generates, for the AD conversion unit, a clock signal for the counting, and the clock signal generating unit switches a frequency of the clock signal, during a period of AD conversion, from a first frequency to a second frequency that is different from the first frequency.

This allows the AD conversion unit to perform AD conversion based on the second frequency lower than the first frequency, after the clock signal generating unit switches the frequency of the clock signal, thus allowing the AD conversion unit to change the resolution for the AD conversion between before and after the switching. As a result, it is possible to expand the dynamic range.

In addition, the second frequency may be lower than the first frequency.

This allows increasing resolution for performing AD conversion when the voltage of the pixel signal is low, and decreasing resolution for performing AD conversion when the voltage of the pixel signal is high, thus improving S/N at a low illuminance side.

In addition, the clock signal generating unit may include: a divider which divides a frequency of a reference clock signal so as to generate the clock signal; and a switching unit which switches a division ratio of the divider from a first division ratio corresponding to the first frequency to a second division ratio corresponding to the second frequency, at a point when a first period elapses since a start of the ramp waveform signal.

This allows the clock signal generating unit to switch the frequency of the clock signal from the first frequency to the second frequency by dividing the frequency of the reference clock signal at different division ratios, without including a plurality of oscillators for generating clock signals of the first and the second frequencies.

In addition, the clock signal generating unit may further include a counter for counting the number of clocks of the clock signal from the start of the ramp waveform signal, and the switching unit may switch the division ratio from the first division ratio to the second division ratio at a point when the number of counts of the counter exceeds a predetermined value.

This allows arbitrary setting of timing for switching the frequency of the clock signal, or allows, with this timing, changing a width of expansion of the dynamic range. Specifically, the earlier the timing for switching the frequency of the clock signal is during a period of AD conversion, the more the dynamic range can be extended.

In addition, the period of AD conversion may include a first period and a second period, the clock signal generating unit may generate a clock signal having the first frequency during the first period and generate a clock signal having the second frequency during the second period, and the first period may be shorter than the second period.

This allows intensively increasing the resolution when the voltage of the pixel signal is low, that is, at the time of low illuminance. Thus, it is possible to further increase S/N of the low illuminance side. In addition, by keeping the resolution low when the voltage of the pixel signal is high, it is possible to keep a wide input range for AD conversion.

In addition, the AD conversion unit may include: a count unit which counts the number of clocks of the clock signal; and a latch unit which holds a count value of the count unit when the ramp waveform signal matches the voltage of the pixel signal.

In addition, a digital camera according to the present invention includes the solid-state imaging device described above.

In addition, the present invention can be realized not only as a solid-state imaging device and a digital camera, but also as an AD conversion method.

According to the present invention, it is possible to provide a solid-state imaging device whose dynamic range is expanded using a simple configuration.

### FURTHER INFORMATION ABOUT TECHNICAL BACKGROUND TO THIS APPLICATION

The disclosure of Japanese Patent Application No. 2008-331626 filed on Dec. 25, 2008 including specification, drawings and claims is incorporated herein by reference in its entirety.

The disclosure of PCT application No. PCT/JP2009/007058 filed on Dec. 21, 2009, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a block diagram showing a configuration of a solid-state imaging device according to an embodiment of the present invention;

FIG. 2 is a timing chart showing an operation in the clock generating unit 12 and the clock control unit 13;

FIG. 3 is a timing chart showing detection of a voltage level of a pixel signal in the case of inputting a counter clock CLKAD having a constant frequency into an AD conversion unit;

FIG. 4 is a timing chart showing detection of a voltage level of a pixel signal in the case of switching the frequency of the counter clock CLKAD;

FIG. 5A is a graph showing an expansion of dynamic range by switching the frequency of the counter clock CLKAD;

FIG. 5B is a graph indicating a value after AD conversion with respect to an amount of incident light;

FIG. 6A is a graph showing an expansion of dynamic range in the case of switching the frequency of the counter clock CLKAD a plurality of times;

FIG. 6B is a graph indicating a value after AD conversion with respect to an amount of incident light;

FIG. 7 is a diagram showing an outline configuration of a digital camera including the solid-state imaging device according to the present invention;

FIG. 8A is an external view showing an example of the digital camera; and

FIG. 8B is an external view of an example of a video camera including the solid-state imaging device according to the present invention.

### DESCRIPTION OF THE PREFERRED EMBODIMENT

Hereinafter, an embodiment of the present invention will be described with reference to the drawings. Note that the embodiment described below is merely an example and can be modified in various manners.

A solid-state imaging device according to the present invention includes: an imaging unit having a plurality of pixels arranged in a matrix; a column signal line provided per column in the imaging unit; an analog-to-digital (AD) conversion unit which converts, into a digital value, a voltage of a pixel signal from the column signal line by performing counting for a period of time until a ramp waveform signal reaches the voltage of the pixel signal; and a clock signal generating unit which generates, for the AD conversion unit, a clock signal for the counting, and the clock signal generating unit switches a frequency of the clock signal, during a period of AD conversion, from a first frequency to a second frequency that is different from the first frequency. This allows increasing resolution for performing AD conversion when the voltage of the pixel signal is low, and decreasing resolution for performing AD conversion when the voltage of the pixel signal is high, thus improving S/N at the low illuminance side.

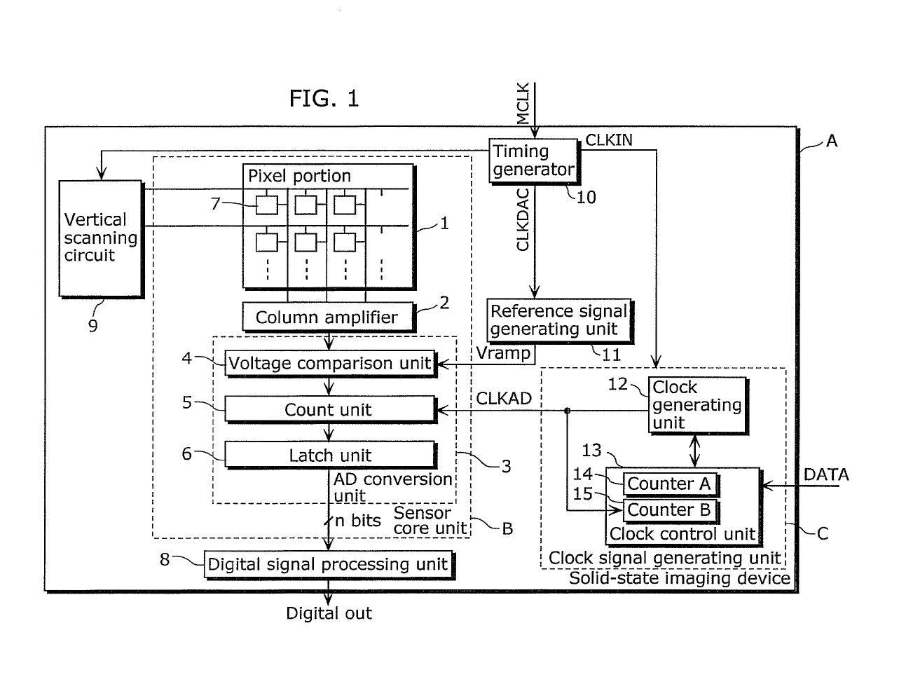

FIG. 1 is a block diagram showing a configuration of a solid-state imaging device according to an embodiment of the present invention. A solid-state imaging device A shown in the figure is a column MOS image sensor. Specifically, the solid-state imaging device A includes: a sensor core unit B, a digital signal processing unit 8, a vertical scanning circuit 9, a timing generator 10, a reference signal generating unit 11, and a clock signal generating unit C.

The sensor core unit B outputs a digital value according to an intensity of incident light. Specifically, the sensor core unit B includes: a pixel portion 1, a column amplifier 2, and a column analog-to-digital converter (hereinafter, AD conversion unit) 3.

The pixel portion 1 includes unit pixels 7 arranged in a matrix and outputs, per row, a pixel signal that is a signal corresponding to an amount of light received by the unit pixels 7 to a column signal line provided per column of the unit pixels 7, according to a signal output from the vertical scanning circuit 9. This pixel portion 1 functions as an imaging unit.

The column amplifier 2 amplifies the pixel signal corresponding to each column signal line.

The AD conversion unit 3 outputs a digital value corresponding to each pixel signal by performing digital conversion on each pixel signal amplified by the column amplifier 2. Specifically, the AD conversion unit 3 includes: a voltage comparison unit 4 which compares the voltage of the pixel signal with a reference signal voltage; a count unit 5 which performs counting processing in parallel with the comparison processing performed by the voltage comparison unit 4; a latch unit 6 which obtains a digital value of the voltage of the pixel signal by holding the count value at the point when the comparison processing by the voltage comparison unit 4 is completed. The voltage comparison unit 4 compares the voltage of the pixel signal with a voltage of a reference signal Vramp that is output from the reference signal generating unit 11, and outputs a signal indicating timing with which the voltage of the reference signal Vramp has reached the voltage of the pixel signal. In addition, the count unit 5 performs counting based on a counter clock CLKAD that is output from a clock generating unit 12, for a period of time from when the reference signal Vramp is generated to when the reference signal Vramp reaches the voltage of the pixel signal. The latch unit 6 holds the count value of the count unit 5 at a point when the voltage comparison unit 4 outputs a signal indicating the timing with which the reference signal has reached the voltage of the pixel signal. In other words, the latch unit 6 holds a digital value corresponding to the voltage of the pixel signal, and outputs, to the digital signal processing unit 8, a digital signal that is the digital value that is held.

The digital signal processing unit 8 performs digital gain calculation, different types of correction processing, and the like on the digital signal output from the AD conversion unit 3, and outputs a processed digital signal to the outside of the solid-state imaging device A.

The vertical scanning circuit 9 is disposed adjacent to the pixel portion 1, and sequentially outputs, per row of the unit pixels 7, a row selection signal for controlling a period for accumulating the charges generated in each of the unit pixels 7 and reading the pixel signal in each of the unit pixels 7 to the column signal line in units of rows, according to a pulse output from the timing generator 10. For example, the vertical scanning circuit 9 is a shift register.

The timing generator 10 is a circuit which controls operation timing of each processing unit, and operates in synchronization with a master clock MCLK supplied from outside. Specifically, the timing generator 10 controls: timing for the vertical scanning circuit 9 to output a row selection signal; timing for the reference signal generating unit 11 to generate a reference signal; and timing for the clock generating unit 12 to generate the counter clock CLKAD.

The reference signal generating unit 11 operates in conjunction with a ramp clock CLKDAC that is input from the timing generator 10, so as to generate the reference signal Vramp for AD conversion. Specifically, the reference signal Vramp has a ramp waveform.

The clock signal generating unit C generates, to the AD conversion unit 3, a counter clock CLKAD that is a clock signal for counting. Specifically, the clock signal generating unit C includes the clock generating unit 12 and a clock control unit 13.

The clock generating unit 12 generates, based on the value input from the clock control unit 13, a counter clock CLKAD in synchronization with the clock CLKIN generated by the timing generator 10. In addition, the clock generating unit 12 outputs a resetting signal to the clock control unit 13. The clock generating unit 12 will be described in detail later along with the description of the clock control unit 13.

The clock control unit 13 counts the counter clock CLKAD generated by the clock generating unit 12, and outputs the count value to the clock generating unit 12. In addition, to the clock control unit 13, a first frequency set value fAD0, a second frequency set value fAD1, and a frequency switching value ADCnt0 are input from outside. Specifically, the clock control unit 13 includes a counter A14 and a counter B15. The counter A14 is a counter which increments the count by one in synchronization with a rising edge and a falling edge of the clock CLKIN. The counter B15 is a counter which increments the count by one up to a full range of the AD conversion by the AD conversion unit 3, in synchronization with the rising edge of the counter clock CLKAD generated by the clock generating unit 12. The clock control unit 13 outputs, to the clock generating unit 12, the count values of the counters A14 and B15.

Next, the operation of the clock generating unit for generating the counter clock CLKAD based on the count value output from the clock control unit 13 will be described.

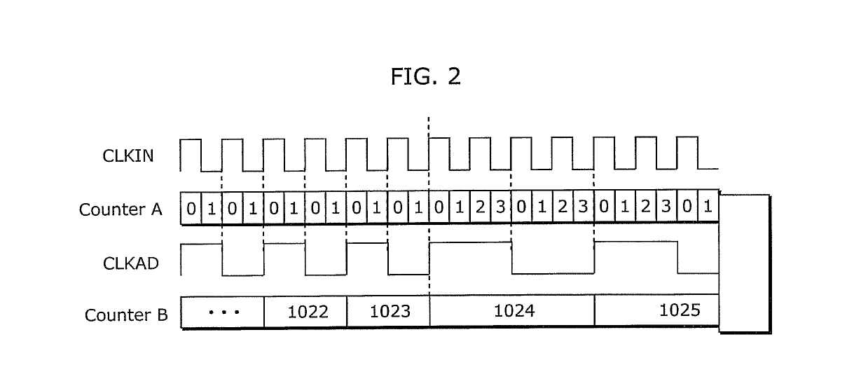

FIG. 2 is a timing chart showing an operation performed in the clock generating unit 12 and the clock control unit 13. Here, it is assumed that: the number of output bits of the AD conversion unit 3 is 12 bits (LSB); the first frequency set value fAD0 is 1; the second frequency set value fAD1 is 3; and the frequency switching value ADCnt0 is 1023. The figure shows: the clock CLKIN to be input into the clock control unit 13; the count value of the counter A14; the counter clock CLKAD to be output from the clock generating unit 12; and the count value of the counter B15.

First, the counter A14 increments the value by one in synchronization with the rising and falling edges of the clock CLKIN output from the timing generator 10. The clock generating unit 12 determines whether or not the count value of the counter 14 has reached the first frequency set value fAD0. When the count value of the counter A14 does not reach the first frequency set value fAD0, the clock generating unit 12 outputs the counter clock CLKAD without inverting it. On the other hand, when the count value of the counter A14 reaches the first frequency set value fAD0, the clock generating unit 12 inverts the output of the counter clock CLKAD at the next rising or falling edge of the clock CLKIN, and resets the count value of the counter 14.

In other words, the counter A14, repeats an operation of counting by one, until the count value becomes 1, in synchronization with the rising and falling edges of CLKIN that is input into the clock generating unit 12 and resetting the count value to 0 when the count value becomes 1. In addition, the clock generating unit 12 inverts the output of the counter clock CLKAD each time the count value of the counter A14 reaches 1 that is the first frequency set value fAD0.

With this, the counter clock CLKAD becomes a signal having a cycle that is double a cycle of the clock CLKIN. In other words, the clock generating unit 12 functions as a divider which divides the clock CLKIN at a division ratio that is double the first frequency set value fAD0 held by the counter A14.

In addition, the counter B15 increments the count by one in synchronization with the rising edge of the counter clock CLKAD. The clock generating unit 12 determines whether or not the count value of the counter B15 has reached the frequency switching value ADCnt0. In the case where the count value of the counter B15 has not reached the frequency switching value ADCnt0, the clock generating unit 12 generates the counter clock CLKAD, based on whether or not the count value of the counter A14 has reached the first frequency set value fAD0.

On the other hand, in the case where the count value of the counter B15 has reached 1023 that is the frequency switching value ADCnt0, the clock generating unit 12 generates, after the next rising edge of the counter clock CLKAD, the counter clock CLKAD, based on whether or not the count value of the counter A14 has reached 3 that is the second frequency set value fAD1. Subsequently, in the same manner, when the count value of the counter A14 reaches 3 that is the second frequency set value fAD1, the clock generating unit 12 inverts the output of the counter clock at the next rising and falling edges of the clock CLKIN, and resets the count value of the counter A14.

With this, the counter clock CLKAD, after the count value of the counter B15 has reached the frequency switching value ADCnt0, becomes a signal having a cycle that is four times a cycle of the clock CLKIN. In other words, the counter clock CLKAD becomes a signal having a cycle resulting from the division at a division ratio that is double the second frequency set value fAD1.

Thus, the clock generating unit 12 switches the frequency of the counter clock CLKAD at the point when the count value of the counter B15 exceeds the frequency switching value ADCnt0. In other words, the clock generating unit 12 also functions as a switching unit which switches from a first division ratio fAD0×2 to a second division ratio fAD1×2. Accordingly, the clock generating unit 12 can switch the frequency of the counter clock CLKAD from a first frequency to a second frequency, without including a plurality of oscillators for generating the counter clock CLKAD at different frequencies.

Note that the clock generating unit 12 resets the count value of the counter B15 at the next rising edge of the counter clock CLKAD when all the 12 bits of the count value of the counter B15 are 1.

In addition, as shown in this example, the counters A14 and B15 may perform counting in synchronization with the rising or falling edge of a referential clock, or in synchronization with both the rising and falling edges of the referential clock.

Next, detecting the voltage of the pixel signal which corresponds to the column signal line and is input into the AD conversion unit 3 will be described.

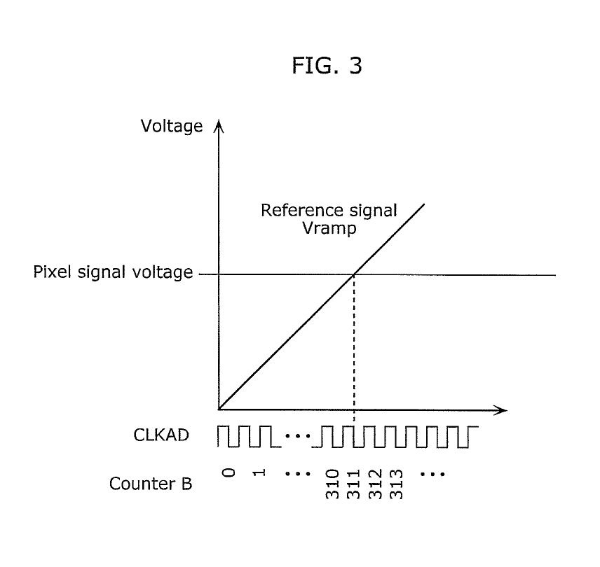

FIG. 3 is a timing chart showing detection of a voltage level of the pixel signal in the case of inputting the counter clock CLKAD having a constant frequency into the AD conversion unit 3. The figure shows: a pixel signal to be input into the voltage comparison unit 4; the reference signal Vramp to be input into the voltage comparison unit 4; and timing for the counter clock CLKAD to be input into the count unit 5.

The voltage comparison unit 4 sequentially compares the voltage of the reference signal Vramp varying in a ramp state, with the voltage of the pixel signal. In addition, the counter unit 5 performs the operation of counting based on the counter clock CLKAD. The latch unit 6 holds the count value that is counted by the count unit 5 when the voltage of the reference signal Vramp and the voltage of the pixel signal match, and outputs, as the digital data, the count value that is held to the digital signal processing unit 8.

Thus, the AD conversion unit 3 performs AD conversion by comparing the voltage of the reference signal Vramp with the voltage of the pixel signal, and extracting, as the digital data corresponding to the voltage of the pixel signal, the count value of the count unit 5 at the point when the voltage of the reference signal Vramp reaches the voltage of the pixel signal.

Next, the following will describe the detection of the voltage of the pixel signal in the case of switching the frequency of the counter clock CLKAD that is input into the AD conversion during the period of the AD conversion.

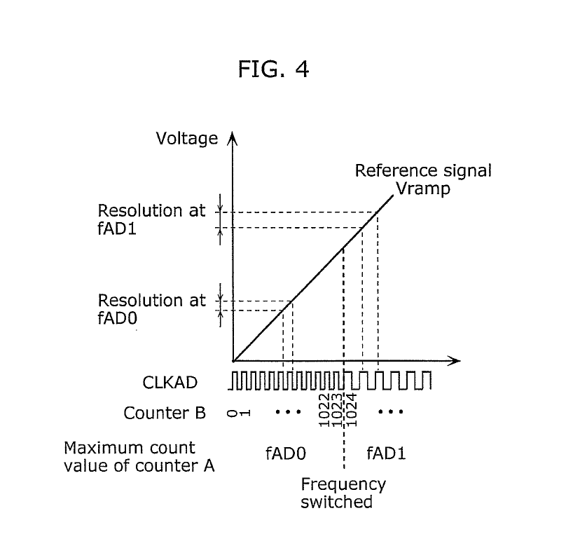

FIG. 4 is a timing chart showing the detection of the voltage level of the pixel signal in the case of switching the frequency of the counter clock CLKAD that is input into the AD conversion unit 3. The figure shows, compared to FIG. 3, the frequency of the counter clock CLKAD that is different before and after the frequency switching. For example, when the frequency switching value ADCnt0 is 1023, the frequency of the counter clock CLKAD becomes low from the next rising edge of the counter clock CLKAD after the count value of the counter B15 reaches 1023.

Since the reference signal Vramp is a waveform in which the voltage increases with respect to time at a constant ratio, the smaller temporal variation is, the less variation occurs in the corresponding voltage. In addition, the counter clock CLKAD has a shorter cycle in a period of time in which a maximum count value of the counter A14 is the first frequency set value fAD0 than in a period of time in which the maximum count value of the counter 14 is the second frequency set value fAD1. Accordingly, this shows that: comparing the resolution of the voltage during a period before the count value of the counter B15 exceeds the frequency switching value ADCnt0 and the resolution of the voltage after the count value of the counter B15 exceeds the frequency switching value ADCnt0, the resolution before exceeding the frequency switching value ADCnt0 is higher than the resolution after exceeding.

Thus, the solid-state imaging device A according to the present invention is capable of performing AD conversion with the resolution of the pixel signal, which is differentiated by changing the frequency of the counter clock CLKAD input into the count unit 5. The higher the frequency of the counter clock CLKAD is, the finer AD conversion can be performed on the signal to be converted within a voltage range, thus allowing AD conversion with increased resolution.

Next, expansion of the dynamic range in the solid-state imaging device A of the present invention will be described. Specifically, the following will describe expansion of the dynamic range by changing the frequency of the counter clock CLKAD that is input into the AD conversion unit 3.

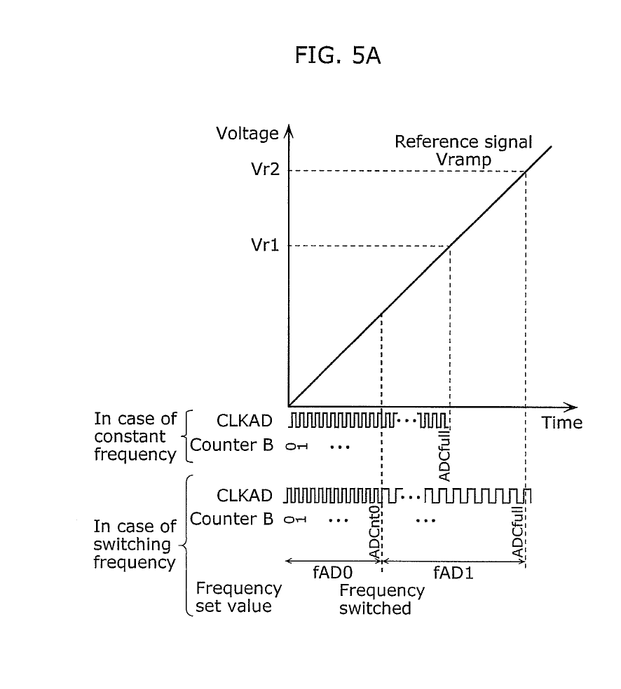

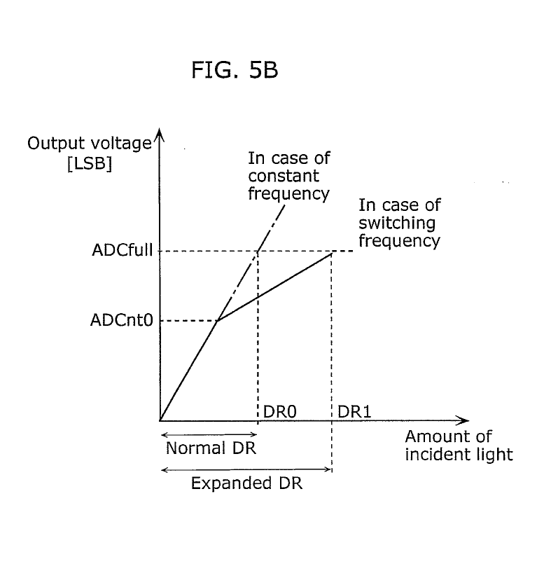

FIG. 5A is a graph indicating a voltage range which allows AD conversion, in the case of the counter clock CLKAD having a constant frequency and the case of changing the frequency in the middle of the conversion. In the figure, the frequency of the counter clock CLKAD in the case of the counter clock CLKAD having a constant frequency is equivalent to the frequency before switching in the case of switching the frequency, that is, the frequency determined by the first frequency set value fAD0.

In FIG. 5A, a horizontal axis indicates: the timing of the counter clock CLKAD and the count value of the corresponding counter B15, in the case of the counter clock CLKAD having a constant frequency and the case of switching the counter clock CLKAD. ADCfull represents a count value when the counter B15 is saturated. For example, ADCfull is 4095 when the counter B15 is a 12-bit counter.

In addition, a vertical axis indicates the voltage of the reference signal Vramp corresponding to the count value. Here, Vr1 is a voltage when the count value of the counter B15 becomes ADCfull in the case of the counter clock CLKAD having a constant frequency. In addition, Vr2 is a voltage when the count value of the counter B15 becomes ADCfull in the case of switching the counter clock CLKAD in the middle.

As shown in the figure, Vr2 that is a saturation level voltage in the case of switching the frequency to a lower frequency in the middle is higher than Vr1 that is a saturation level voltage in the case of the counter clock CLKAD having a constant frequency. This is because, switching the frequency to a lower frequency in the middle increases a period of time required for the count value after the switching, and results in an increase in AD-convertible voltage by a width of the reference signal Vramp corresponding to the extended time.

FIG. 5B is a graph indicating a value after performing the AD conversion with respect to the amount of incident light, in the case of switching the frequency of the counter clock CLKAD. In the figure, the horizontal axis indicates the amount of incident light that is an amount of light incident on the unit pixels 7, and the vertical axis indicates the count value of the counter B15.

In the case of the counter clock CLKAD having a constant frequency, the resolution of the AD conversion unit 3 is always constant. In contrast, in the case of switching the frequency of the counter clock CLKAD, the resolution of the AD conversion unit 3 is different before and after switching the frequency of the counter clock CLKAD.

This is because, for example, when the second frequency set value fAD1 indicates a value that is double the first frequency set value fAD0 (for example, when fAD01 is 1 and fAD1 is 3), the counter clock CLKAD generated based on fAD1 has a cycle that is double a cycle of the counter clock CLKAD generated based on fAD0. Accordingly, after the count value of the counter B15 exceeds the frequency switching value ADCnt0, and the clock generating unit 12 switches the frequency of the counter clock CLKAD, the resolution for the AD conversion becomes half the resolution before the switching. In other words, after the switching, the gain of the output signal corresponding to the amount of incident light becomes one-half.

This allows further expanding, from DR0 to DR1, the dynamic range in the case of performing AD conversion by switching the frequency of the counter clock CLKAD in the middle, compared to the case of performing AD conversion with a constant counter clock CLKAD. The difference in the dynamic range (DR1-DR0) is a value calculated by dividing, by a ratio of the resolution after the switching with respect to the resolution before the switching, the difference between the amount of incident light corresponding to the full range of the AD conversion in the case of performing the AD conversion with a constant counter clock CLKAD and the amount of incident light corresponding to the output signal in the AD conversion at the time of switching the frequency.

For example, when the counter B15 is a 12-bit counter (0 to 4095), ADCnt0 is 1023, fAD0 is 1, and fAD1 is 3, the dynamic range increases by 7/4 times as compared to the dynamic range in the case of performing, without switching the frequency, the AD conversion at the same frequency as the frequency of the counter clock CLKAD when the FAD0 is 1.

Thus, by setting the value of the frequency switching value ADCnt0 to an arbitrary value within a range of the counter B15, it is possible to arbitrarily change the timing for the clock generating unit 12 to switch the frequency of the counter clock CLKAD. In addition, it is possible to change the width of expansion of the dynamic range according the value of the frequency switching value ADCnt0. Specifically, the smaller the frequency switching value ADCnt0 is set, the further the dynamic range can be expanded.

As described above, the solid-state imaging device A according to the present invention is capable of changing the resolution for AD conversion between before and after switching the frequency of the counter clock CLKAD. This allows increasing resolution when the voltage of the pixel signal is low, and decreasing resolution when the voltage of the pixel signal is high, thus expanding the dynamic range and dealing with even incident light of higher intensity.

Note that the clock generating unit 12 may change the frequency of the counter clock CLKAD a plurality of times. Next, expansion of the dynamic range in the case of switching, a plurality of times, the frequency of the counter clock CLKAD input into the AD conversion unit 3 will be described.

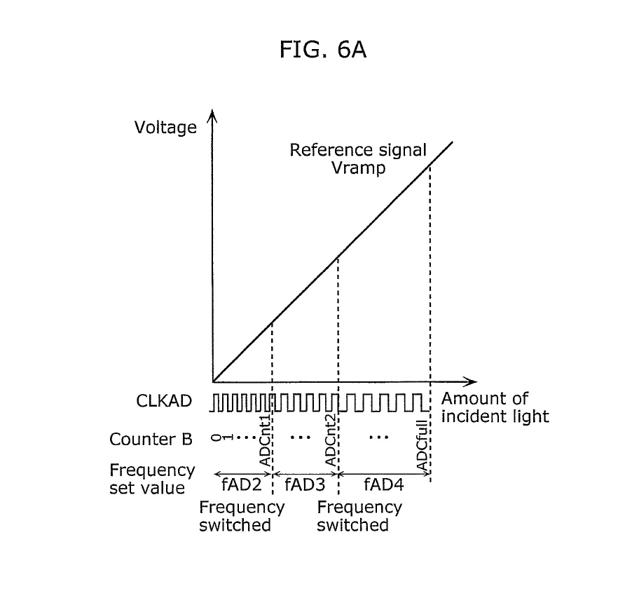

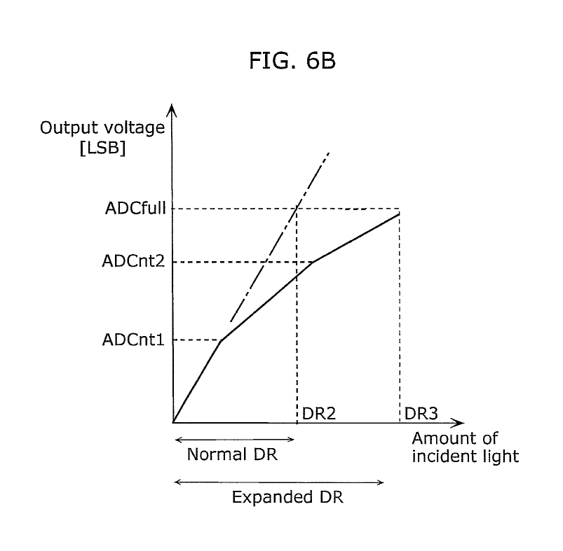

FIG. 6 is a graph indicating a voltage range which allows AD conversion in the case of switching the frequency of the counter clock CLKAD a plurality of times.

For example, as shown in FIG. 6A, a plurality of frequency set values and frequency switching values are set such as: a first frequency set value fAD2, a second frequency set value fAD3, and a third frequency set value fAD4; and a first frequency switching value ADCnt1 and a second frequency switching value ADCnt2.

FIG. 6B is a graph indicating a value after performing AD conversion with respect to the amount of incident light in the case of switching the frequency of the counter clock CLKAD a plurality of times.

In this case, as shown in the figure, the resolution changes more than one time.

In the case of switching the frequency of the counter clock CLKAD a plurality of times, the counter A14 which performs counting in synchronization with the rising and falling edges of the clock CLKIN repeats the counting up to fAD2 until the count value of the counter B15 which performs counting in synchronization with the rising edge of the counter clock CLKAD reaches the first frequency switching value ADCnt1, and the clock generating unit 12 generates a counter clock CLKAD having a cycle corresponding to fAD2. Likewise, the following operation is sequentially performed: the counter A14 repeats the counting up to the second frequency set value fAD3 until the count value of the counter B15 reaches the second frequency switching value ADCnt2, and the clock generating unit 12 generates the counter clock CLKAD having a cycle corresponding to fAD3.

Here, as shown in FIG. 6B, by setting FAD4>fAD3>fAD2, it is possible to further roughen the resolution for AD conversion at a high illuminance side as compared to the resolution at a low illuminance side. This allows further expanding the dynamic range, from DR2 to DR3, in the case of performing AD conversion by switching the frequency of the counter clock CLKAD in the middle a plurality of times, as compared to the case of performing AD conversion with a constant counter clock CLKAD.

In addition, this allows setting a plurality of frequency set values and frequency switching values, and allows, by sequentially increasing the set values, roughening the resolution for AD conversion at the high illuminance side as compared to the resolution for AD conversion at the low illuminance side, thus allowing further expansion of the dynamic range.

Generally, in signal processing in an imaging device such as a digital camera, processing such as gamma correction or knee correction is performed, and processing for amplifying a signal of middle or low illuminance level with respect to the obtained image signal and compressing a signal of high illuminance is performed. In performing such processing, by increasing the resolution of the signal of middle or low illuminance level, it is possible to improve S/N in a signal component of a region amplified by the signal processing that is to be performed in a subsequent stage, thus improving image quality.

In addition, the clock control unit 13, in the case of switching the frequency of the counter clock CLKAD in the middle, the period of the reference signal Vramp is changed according to the frequency before or after the switching. Specifically, the clock generating unit 12 outputs, to the clock control unit 13, information indicating the frequency of the counter clock CLKAD that is being output by the clock generating unit 12. The clock control unit 13 is designed to output the reference signal Vramp up to a point in time when the count value of the counter B15 is saturated, based on the information indicating the frequency of the counter clock CLKAD that is output from the clock generating unit 12.

Note that in FIGS. 5A and 5B in the embodiment above, the description has been given on an example of expanding the dynamic range when the frequency in the case of the counter clock CLKAD having a constant frequency and the frequency in the case of the frequency of the counter clock CLKAD corresponding to the first frequency set value fAD0 are the same, but the counter clock CLKAD corresponding to the first frequency set value fAD0 may have a frequency higher than the frequency in the case of the counter clock CLKAD having a constant frequency. In this case, compared to the case of the counter clock CLKAD having a constant frequency, it is possible to further raise the resolution at the low illuminance side.

This allows expanding the dynamic range to the lower illuminance side as compared to the dynamic range in the case of the counter clock CLKAD having a constant frequency.

In addition, in the solid-state imaging device A according to the present invention, the period of AD conversion includes a first period and a second period, and the clock generating unit 12 may generate a counter clock CLKAD of the first frequency in the first period, and may generate a counter clock CLKAD of the second frequency that is lower than the first frequency in the second period, and the first period may be set shorter than the second period.

With this, by intensively increasing the resolution when the voltage of the pixel signal is low, it is possible to amplify the signal component at the low illuminance side, thus improving S/N at the low illuminance side. In addition, by keeping the resolution low when the voltage of the pixel signal is high, it is possible to keep a wide input range for AD conversion.

In addition, in the solid-state imaging device A according to the present invention, the AD conversion unit 3 includes the count unit 5, but the AD conversion unit 3 need not include the count unit 5. If this is the case, the latch unit 6 holds the count value of the counter B15 at the point when the voltage comparison unit 4 outputs the signal indicating the timing with which the reference signal Vramp has reached the voltage of the pixel signal. This allows simplifying the configuration of the AD conversion unit 3 and reducing the size of the solid-state imaging device.

In addition, in the embodiment descried above, the clock generating unit 12 keeps the frequency of the counter clock CLKAD high at the low illuminance side of the image signal and low at the high illuminance side of the pixel signal, but the frequency of the counter clock CLKAD need not be limited to this. For example, the frequency of the pixel signal may be high at the high illuminance side of the pixel signal and low at the low illuminance side of the pixel signal. In addition, for example, the frequency of the counter clock CLKAD may be high in an arbitrary illuminance range of the pixel signal.

This allows further amplifying the signal component within the arbitrary illuminance range of the pixel signal, thus improving S/N. In addition, outside the arbitrary illuminance range, it is possible to keep a wide dynamic range by lowering the frequency of the counter clock CLKAD and thereby lowering the resolution.

In addition, the present invention can be realized not only as a solid-state imaging device but also as an AD conversion method for controlling the solid-state imaging device.

(Configuration of the Digital Camera)

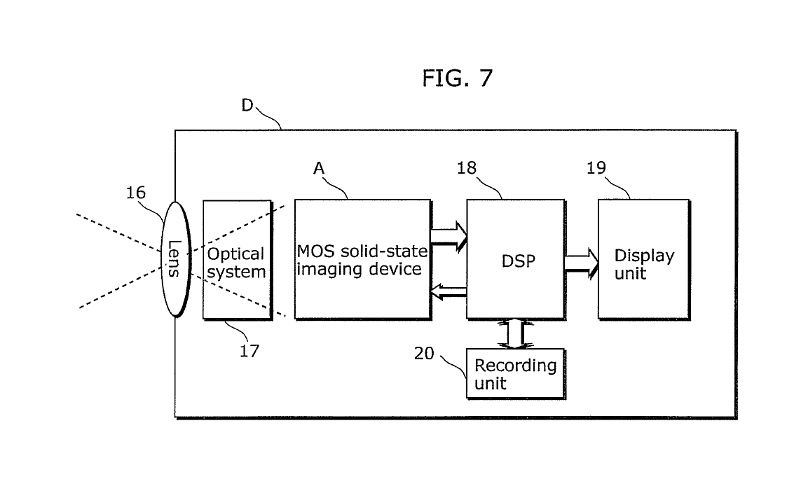

In addition, it goes without saying that the present invention includes various electronic devices which include the solid-state imaging device A according to an implementation of the present invention. FIG. 7 is a diagram showing an outline configuration of a digital camera using the solid-state imaging device A as described above.

As shown in FIG. 7, a digital camera D includes: a lens 16 which forms an optical image of an object on an imaging element; an optical system 17 including a diaphragm, a mirror, and a shutter, which performs optical processing on the optical image having passed through the lens 16; the solid-state imaging device A of MOS type; a DSP 18 which performs drive control on the solid-state imaging device A and processes the image signal obtained from the solid-state imaging device A; a display unit 19 which displays the obtained image on a display apparatus such as a monitor; and a recording unit 20 which records the image onto a predetermined recording medium.

The optical image from the object is adjusted into appropriate brightness by the lens 16 and the diaphragm in the optical system 17, to be incident onto the solid-state imaging device A. When this happens, the lens 16 adjusts a focal position such that the optical image from the object is formed on the pixel portion 1 included in the solid-state imaging device A. The DSP18 performs drive control on the solid-state imaging device A through a communication unit such as a serial I/F, and it is also possible to set, using this communication unit, the frequency set values and frequency switching values for the clock control unit 13 in the solid-state imaging device A. The DSP18, on the image signal received from the solid-state imaging device A, performs various types of correction processing such as gamma correction, knee correction, white balance, and noise reduction, as well as YC processing, image compression processing, and so on, and outputs an image signal to the display unit 19 or the recording unit 20.

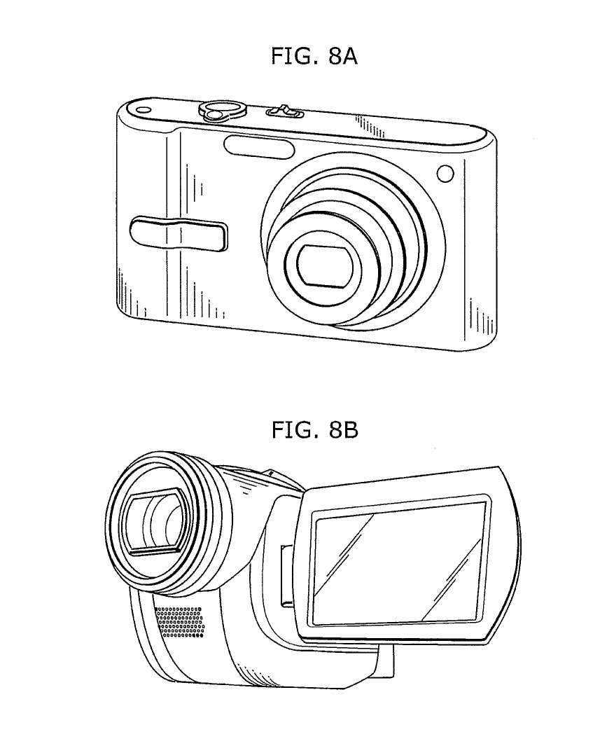

With the digital camera D thus configured, it is possible to expand the dynamic range using the solid-state imaging device A according to an implementation of the present invention, thus improving S/N at the low illuminance side and improving the image quality. In addition, since this allows suppressing increase in chip area in the solid-state imaging device A, it is possible to realize a compact digital camera, for example, as a digital still camera as shown in FIG. 8A or a video camera as shown in FIG. 8B. Note that in FIGS. 8A and 8B, each of the solid-state imaging device A, the DSP18, and the recording unit 20 may be appropriately combined into one chip.

Thus far, the solid-state imaging device according to an embodiment of the present invention has been described, but the present invention is not limited to the embodiment.

Although only an exemplary embodiment of this invention has been described in detail above, those skilled in the art will readily appreciate that many modifications are possible in the exemplary embodiment without materially departing from the novel teachings and advantages of this invention. Accordingly, all such modifications are intended to be included within the scope of this invention.

### INDUSTRIAL APPLICABILITY

A solid-state imaging device according to an implementation of the present invention can be realized as a solid-state imaging device having a simple configuration and a high dynamic range which is less likely to be saturated with a large amount of incident light, and the solid-state imaging device is applicable to, for example: a digital camera that is best suited for capturing conditions in which the amount of light significantly changes between indoors and outdoors, and other various camera systems using the solid-state imaging device, such as a camera cellular phone and a monitoring camera.

What is claimed is:

1. A solid-state imaging device, comprising:
an imaging unit having a plurality of pixels arranged in a matrix;
a column signal line provided per column in said imaging unit;
an analog-to-digital (AD) conversion unit configured to convert, into a digital value, a voltage of a pixel signal from said column signal line by performing counting for a period of time until a ramp waveform signal reaches the voltage of the pixel signal; and
a clock signal generating unit configured to generate, for said AD conversion unit, a clock signal for the counting,
wherein said clock signal generating unit is configured to switch a frequency of the clock signal, during a period of AD conversion, from a first frequency to a second frequency that is different from the first frequency.

2. The solid-state imaging device according to claim 1,
wherein the second frequency is lower than the first frequency.

3. The solid-state imaging device according to claim 1,
wherein said clock signal generating unit includes:
a divider which divides a frequency of a reference clock signal so as to generate the clock signal; and
a switching unit configured to switch a division ratio of said divider from a first division ratio corresponding to the first frequency to a second division ratio corresponding to the second frequency, at a point when a first period elapses since a start of the ramp waveform signal.

4. The solid-state imaging device according to claim 3,
wherein said clock signal generating unit further includes
a counter for counting the number of clocks of the clock signal from the start of the ramp waveform signal, and
said switching unit is configured to switch the division ratio from the first division ratio to the second division ratio at a point when the number of counts of said counter exceeds a predetermined value.

5. The solid-state imaging device according to claim 2,
wherein the period of AD conversion includes a first period and a second period,
said clock signal generating unit is configured to generate a clock signal having the first frequency during the first period, and generate a clock signal having the second frequency during the second period, and
the first period is shorter than the second period.

6. The solid-state imaging device according to claim 1,
wherein said AD conversion unit includes:
a count unit configured to count the number of clocks of the clock signal; and
a latch unit configured to hold a count value of said count unit when the ramp waveform signal matches the voltage of the pixel signal.

7. A digital camera comprising the solid-state imaging device according to claim 1.

8. An analog-to-digital (AD) conversion method for controlling a solid-state imaging device which includes: an imaging unit having a plurality of pixels arranged in a matrix; a column signal line provided per column in the imaging unit; and an AD conversion unit which converts, into a digital value, a voltage of a pixel signal from the column signal line, by performing counting for a period of time until a ramp waveform signal reaches the voltage of the pixel signal, said AD conversion method comprising:
performing counting for a period of time from the start of the ramp waveform signal; and
switching a frequency of a clock signal for the counting, from a first frequency to a second frequency that is lower than the first frequency, at a point when a predetermined period of time elapses since a start of the ramp waveform signal.
